(19) United States
(12) Patent Application Publication
(10) Pub. No.: US 2007/0257692 A1
(43) Pub. Date: Nov. 8, 2007

(54) Probe

(76) Inventors: Masami Yakabe, Tokyo (JP); Tomohisa Hoshino, Hyogo (JP); Naoki Ikeuchi, Hyogo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/664,807

(22) PCT Filed: Oct. 31, 2005
(86) PCT No.: PCT/JP05/20016

§ 371 Date: Apr. 6, 2007

(30) Foreign Application Priority Data
Nov. 2, 2004 (JP) 2004-319661

(51) Int. Cl. G01R 31/02

(52) U.S. Cl. 324/762

(57) ABSTRACT

A probe, wherein a beam 3 is cantilevered by a supporter 2 with a predetermined space from a probe substrate 1, and a contact 4 extending in a direction away from the probe substrate 1 is attached to the beam 3. A projection 5 extending toward the probe substrate 1 is formed on the beam 3. Since the projection 5 is brought into contact with the probe substrate 1 when a load is applied to the probe substrate 1, stress imposed on the beam 3 can be dispersed.

### TECHNICAL FIELD

This invention relates to a probe, and for example, to a probe for use in inspecting semiconductor wafers for electrical characteristics.

### BACKGROUND ART

In order to inspect for electrical characteristics in IC chips in which a great number of memory circuits, logic circuits and the other components are formed on a semiconductor wafer, for example, a probe card as disclosed in Japanese unexamined patent publication No. 2000-055936 is used as a contactor. This probe card plays a role in relaying test signals that are sent and received between a tester, which is test equipment, and an IC chip upon the probe card makes contact with an electrode pad on the wafer during the test.

This probe card includes a plurality of probe needles corresponding to a plurality of electrode pads formed on an IC chip, and performs an inspection of the IC chip by bringing each probe needle into electrical contact with each electrode pad.

FIG. 14 illustrates an example of conventional probes. In the probe of FIG. 14, a beam 3 is cantilevered on a probe substrate 1 with a supporter 2 and has an end attached with a downwardly extending contact 4. Downward press of the probe substrate 1 brings an end of the contact 4 into contact with an electrode pad 10 on a wafer to be tested, and then a test signal is supplied to the tester (not shown).

Stable extraction of the test signal cannot be obtained unless a certain amount of load is applied to the contact 4 to increase the contact area between the contact 4 and electrode pad 10 for the purpose of reducing electric resistance upon the contact between the contact 4 and electrode 10. The load applied to the contact 4 by pressing down the probe substrate 1 brings the end of the contact 4 into contact with the electrode pad 10, however changes the beam 3 into a shape in which one end is still supported by the supporter 2 while the other end is raised as shown in FIG. 15. Thus, stress is concentrated at joints of the beam 3 with the contact 4 and with the supporter 2. If more stress is applied than the deformation limit of the material making up the beam 3, the beam 3 may suffer from damage including breakage or non-recoverable deformation including bending.

### DISCLOSURE OF THE INVENTION

It is an object of the present invention to provide a probe capable of preventing damage and deformation of a beam by means of dispersing stress imposed on the beam upon pressing the probe down.

According to this invention, the probe comprises a probe substrate, a beam supported on the probe substrate and having an area opposite the probe substrate with a space therebetween, a contact projecting from the beam and extending in the direction away from the probe substrate. At least one of either probe substrate or beam includes a projection in an area opposite to the other one of the probe substrate or beam. The projection is projected toward the other one of the probe substrate or beam.

According to this invention, when the probe substrate is applied with a load, the projection, which is provided between the probe substrate and beam so as to face either beam or probe substrate, abuts the probe substrate or beam, and therefore stress imposed on joints of the beam with the supporter and with the contact can be dispersed.

In a preferable embodiment, the beam is supported at one end or at both ends on the probe substrate.

Preferably, the projection has an angled end face with one side being higher than the other so that the projection makes surface contact with the opposing member which is to be abutted due to deformation of the beam. Stress can be dispersed to the angled end face abutting the opposing member.

Preferably, at least two projections are provided. The provision of the two projections allows further dispersion of stress. At least one projection of the two projections is arranged on the probe substrate in opposition to the beam, while at least one projection is arranged on the beam in opposition to the probe substrate.

Preferably, the at least one projection on the probe substrate and the at least one projection on the beam are arranged to be laterally spaced from each other or to face each other.

Preferably, the at least two projections are attached on one side and the other side of either probe substrate or beam with a predetermined space between the projections in the direction in which the beam extends. Stress can be dispersed to the at least two projections. The projection arranged on one side is shorter than the projection arranged on the other side.

Another aspect of the invention comprises a probe substrate, a beam supported on the probe substrate and serpentined toward the direction away from the probe substrate, a contact projecting from the beam and extending in the direction away from the probe substrate. The beam includes a projection in an area thereof which faces the other area of the beam formed by curving the beam. The projection projects toward the opposite area of the beam.

Preferably, the projection is made of a shock-absorbing material.

According to this invention, since the probe comprises the projection in at least one area facing either the probe substrate or beam, when the probe substrate is applied with a load, the projection abuts the probe substrate or beam, and therefore stress imposed on joints of the beam with the supporter and with the contact can be dispersed. Thus, the beam can be prevented from damage and deformation.

In addition, according to the invention comprising the probe including the beam that is serpentined toward the direction away from the probe substrate, the projection provided in an area of the beam, which faces the other area of the beam formed by curving the beam, abuts the opposite area of the beam. Even when the probe substrate is applied with a load, stress imposed on the curved portion of the beam can be reduced.

### BRIEF DESCRIPTION OF THE DRAWINGS

FIG. 1 illustrates a probe according to one embodiment of the invention.

FIG. 2 illustrates behavior of the probe shown in FIG. 1, with a load applied.

FIG. 3 illustrates a probe according to another embodiment of the invention.

FIG. 4 illustrates a probe according to another embodiment of the invention, with a projection formed on a probe substrate.

FIG. 5 illustrates an example of a probe according to yet another embodiment of the invention, with projections each formed on a probe substrate and beam.

FIG. 6 illustrates an example of a probe according to yet another embodiment of the invention, with projections each formed on the probe substrate and beam.

FIG. 7 illustrates an example of a probe according to yet another embodiment of the invention, with a projection having an angled end face formed on the beam.

FIG. 8 illustrates an example of a probe according to yet another embodiment of the invention, with a projection having an angled end face formed on the probe substrate.

FIG. 9 illustrates an example of a probe according to yet another embodiment of the invention, with a plurality of projections formed on the beam.

FIG. 10 illustrates behavior of the probe shown in FIG. 9, with a load applied.

FIG. 11 illustrates behavior of the probe shown in FIG. 9, with more load applied.

FIG. 12 illustrates a probe with a beam supported at both sides according to yet another embodiment of the invention.

FIG. 13 illustrates a probe according to yet another embodiment of the invention.

FIG. 14 illustrates a conventional probe.

FIG. 15 illustrates behavior of the conventional probe with a load applied.

### BEST MODE FOR CARRYING OUT THE INVENTION

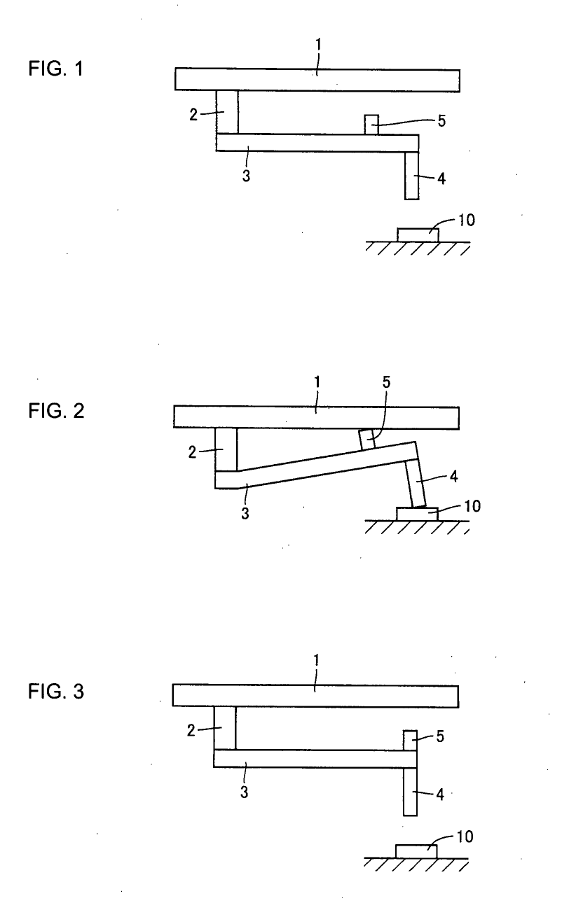

FIGS. 1 and 2 illustrate a probe according to one embodiment of the present invention. In FIG. 1, a beam 3 is cantilevered from a supporter 2 with a predetermined space from a probe substrate 1 and has an area facing the probe substrate 1. A contact 4, which projects from the beam 3 and extends in the direction away from the probe substrate, is attached at an end of the beam 3. A projection 5 acting as a stopper is arranged in the area of the beam 3 opposed to the probe substrate 1 and projects toward the probe substrate 1.

When a load is applied to press down the probe substrate 1 and then an end of the contact 4 is brought into contact with the electrode pad 10 as shown in FIG. 2, the projection 5 abuts the probe substrate 1 and therefore stress is imposed on the abutting region of the end of the projection 5 on the probe substrate 1. Thus, it is possible to disperse the stress that is concentrated at joints of the beam 3 with the supporter 2 and with the contact 4. Consequently, potential damage including breakage of the beam 3 and non-recoverable deformation including bending can be reduced.

Although the material of the projection 5 is not particularly limited, the use of the same material as the beam 3 and contact 4 facilitates manufacture. More preferably, the use of flexible materials provides the projection 5 with a function as a shock absorber. The height of the projection 5 may be determined on the basis of the magnitude of the load to be applied to the probe substrate 1.

FIG. 3 illustrates a probe according to another embodiment of the invention. In this embodiment, the projection 5 is arranged at an end of the beam 3 so as to collinearly align with the contact 4 and oppose the probe substrate 1. When the projection 5 has the same height as the projection 5 in FIG. 1, the end of projection 5, which is collinearly aligned with the contact 4, abuts the probe substrate 1 with a smaller load in comparison with the embodiment shown in FIG. 1, and therefore deformation of the beam 3 can be reduced.

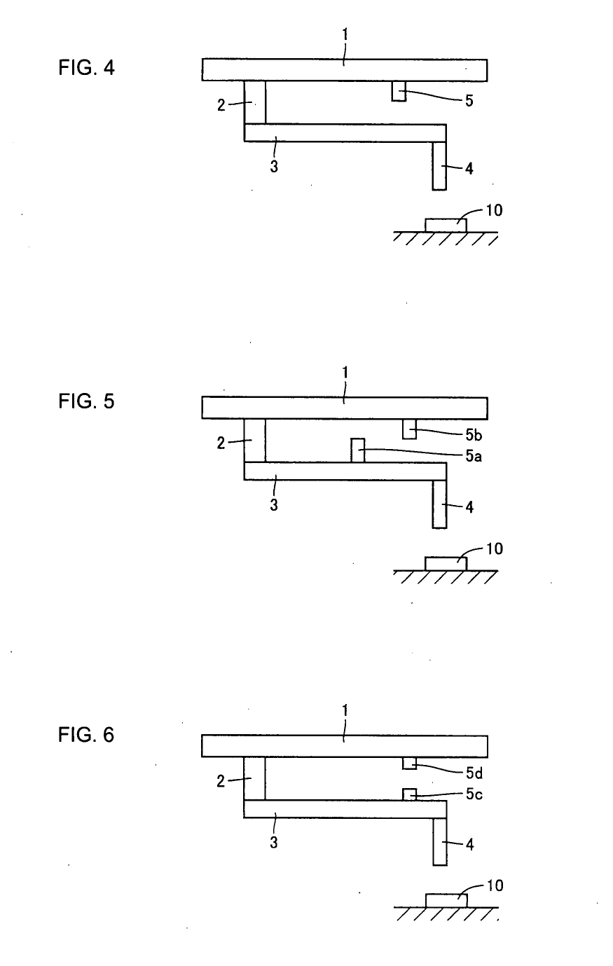

FIG. 4 illustrates a probe according to another embodiment of the invention. The projection 5 of this embodiment is attached on the probe substrate 1 in opposition to the beam 3, and has the same functional effect as those of the embodiments shown in FIGS. 1 and 2.

FIG. 5 illustrates a probe according to yet another embodiment of the invention. This embodiment comprises at least two projections 5a, 5b. Specifically, the projections 5a, 5b are arranged on the beam 3 and probe substrate 1, respectively, so as to oppose the probe substrate 1 and beam 3, respectively, but are laterally spaced from each other. The projection 5a is formed to be slightly longer than the projection 5b.

This embodiment allows the end of the projection 5a to abut the probe substrate 1 and subsequently the end of the projection 5b to abut the beam 3 upon the application of the load to the probe substrate 1, thereby enabling further dispersion of the stress to be imposed on the joints of the beam 3 with the supporter 2 and with the contact 4.

FIG. 6 illustrates a probe according to yet another embodiment of the invention. This embodiment comprises projections 5c, 5d on the beam 3 and the probe substrate 1, respectively, so as to face each other.

This embodiment can disperse the stress imposed on the joints of the beam 3 with the supporter 2 and with the contact 4 by causing the ends of the projections 5c, 5d to abut each other upon the application of the load to the probe substrate 1.

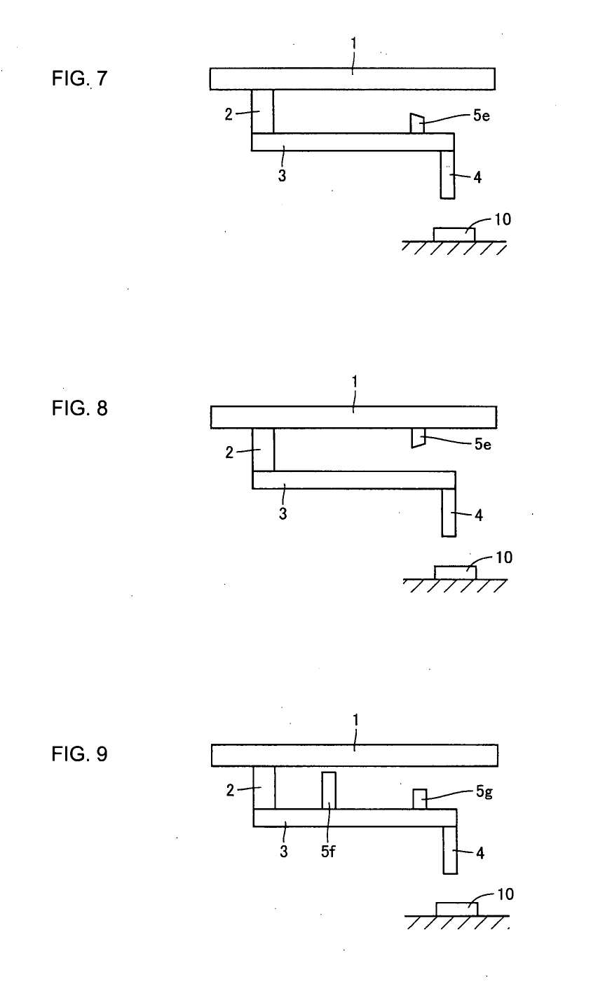

FIG. 7 illustrates a probe according to yet another embodiment of the invention. Similar to the embodiment shown in FIG. 1, this embodiment comprises a projection 5e on the beam 3, however the projection 5e is formed to have an angled end face with one side being higher than the other. When the projection 5e abuts the probe substrate 1 with deformation of the beam 3, the projection 5e makes surface contact with the probe substrate 1.

Because the projection 5 of the embodiment shown in FIG. 1 has an end face formed at a right angle with respect to the direction to which the projection 5 projects, a corner edge of the end of the projection 5 makes point contact with the probe substrate 1. On the contrary, this embodiment having the projection 5e with the angled end face achieves surface contact between the end face of the projection 5e and the probe substrate 1, thereby enabling more preferable dispersion of the stress.

FIG. 8 illustrates a probe according to yet another embodiment of the invention. Similar to the embodiment shown in FIG. 7, this embodiment comprises a projection 5e having an angled end face on the probe substrate 1 in opposition to the beam 3. In this embodiment, when a load is applied to the probe substrate 1, the end face of the projection 5e makes surface contact with the beam 3, thereby enabling dispersion of stress.

FIGS. 9 to 11 illustrate a probe according to yet another embodiment of the invention. This embodiment comprises a plurality of projections 5f, 5g on the beam 3. Specifically, the two projections 5f, 5g are arranged on the beam 3 so as to oppose the probe substrate 1. The projection 5f is arranged near the supporter 2, while the projection 5g is arranged near the contact 4 on the end of the beam 3, along the longitudinal direction of the beam 3, with a predetermined space between the projections 5f and 5g. Preferably, the projection 5f is longer than the projection 5g, and the distance between the projection 5f and probe substrate 1 is shorter than the distance between the projection 5g and probe substrate 1.

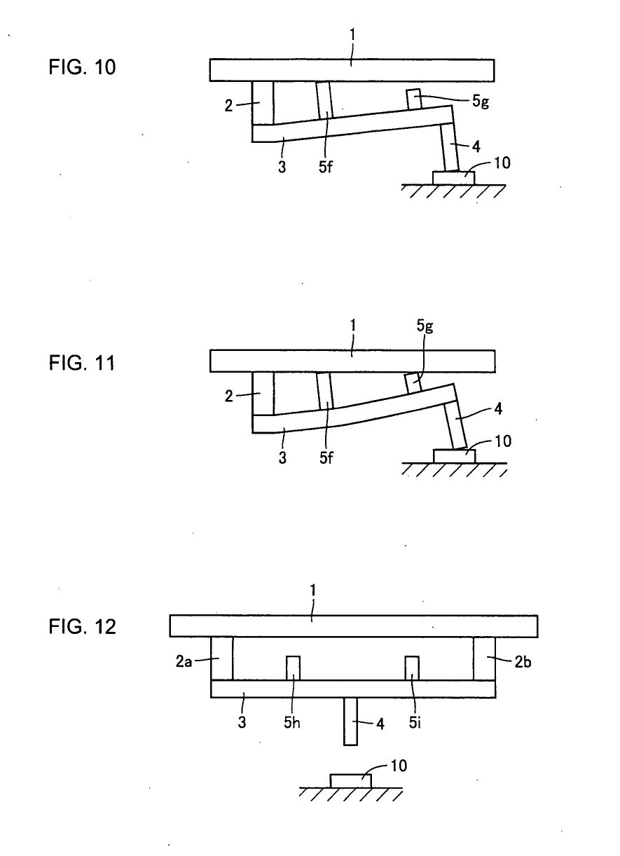

The behavior of the probe according to the embodiment shown in FIG. 9 will be described by referring to FIGS. 10 and 11. When, with gradual application of a load, the end of the contact 4 makes contact with the electrode pad 10, stress is imposed on the joints of the beam 3 with the supporter 2 and with the contact 4 as shown in FIG. 10. Further application of the load causes the end of projection 5f near the supporter 2 to abut the probe substrate 1, and the stress at the joints of the beam 3 with the supporter 2 and with the contact 4 is dispersed.

Further application of the load in order to increase the contact area between the contact 4 and electrode pad 10 for the purpose of reducing the electrical resistance causes the projection 5g near the contact 4 to abut the probe substrate 1 as shown in FIG. 11. Consequently, the stress produced by the application of the load is separated into four points: the joint between the supporter 2 and beam 3; the abutting region of the projection 5f and probe substrate 1; the abutting region of the projection 5g and probe substrate 1; and the joint between the beam 3 and contact 4. By thus dispersing the stress, the stress is not concentrated at the joints of the beam 3 with the supporter 2 and with the contact 4, thereby preventing damage of these joints.

It should be noted that the embodiment shown in FIG. 9 may comprise the projections 5f, 5g having angled end faces as with the embodiments shown in FIGS. 6 and 7.

FIG. 12 illustrates yet another embodiment of the invention. This embodiment is configured to support a beam 3 at both ends on the probe substrate 1. Specifically, the beam 3 has an area facing the probe substrate 1 and opposite ends supported by supporter 2a, 2b on the probe substrate 1. The contact 4 is projected from the beam 3 and extends in the direction away from the probe substrate 1. Between the supporter 2a and contact 4 and between the supporter 2b and contact 4 on the beam 3, projections 5h, 5i are attached so as to project toward the probe substrate 1, respectively.

When a load is applied to the probe substrate 1 in this embodiment to bring the end of the contact 4 into contact with the electrode pad 10, the center portion of the beam 3 is raised toward the probe substrate 1, and stress is concentrated at the joint between the supporter 2a and beam 3 and the joint between the supporter 2b and beam 3. However raising the beam 3 closer to the probe substrate 1 causes the projection 5h, 5i to abut the probe substrate 1, and therefore stress is dispersed to these abutting regions. Consequently, potential damage of the joints of the beam 3 with the supporters 2a, 2b caused by concentration of the stress can be reduced.

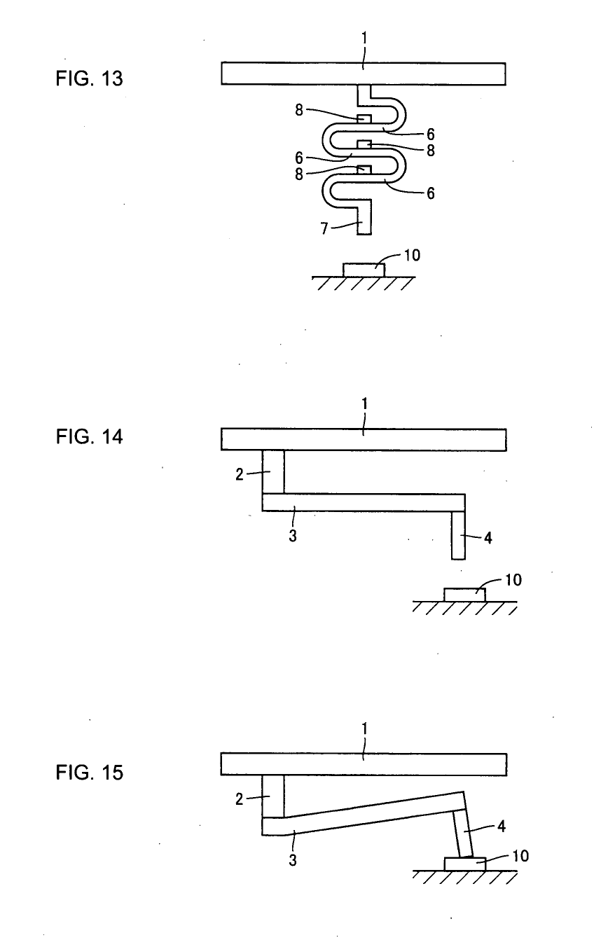

FIG. 13 illustrates a probe according to yet another embodiment of the invention. The probe of this embodiment comprises a plurality of beam portions 6 forming a serpentine shape extending in the direction away from the probe substrate 1. A contact 7 is attached on a distal beam portion 6 so as to project and extend in the direction away from the probe substrate 1. When the end of the contact 7 makes contact with the electrode pad 10, a test signal is extracted.

Once a load is applied to the probe substrate 1, stress is concentrated at the contact 7 and arc-shaped curved portions between the beam portions 6. However, provision of projections 8 each attached in an area of each beam portion 6, which faces the opposite beam portion 6 formed by curving itself, and projecting toward the opposite beam portion 6 allows the projections 8 to abut the opposite areas of the beam portions 6, thereby enabling dispersion of stress to be imposed on the curved portions. This reduces the potential damage of the curved arc portions.

The foregoing has described the embodiments of the present invention by referring to the drawings. However the invention should not be limited to the illustrated embodiments. It should be appreciated that various modifications and changes can be made to the illustrated embodiments within the scope of the appended claims and their equivalents.

### INDUSTRIAL APPLICABILITY

The present invention, which comprises a beam provided with a contact and supported on a probe substrate and a projection provided between the beam and probe substrate, can disperse stress concentrated at a supported point of the beam and a joint between the beam and contact upon application of a load to the probe substrate. Therefore, the present invention can be utilized for probe cards having a plurality of probe needles corresponding to a plurality of electrode pads formed on an IC chip.

What is claimed is:

1. A probe comprising:
a probe substrate;
a beam supported on said probe substrate and having an area opposite said probe substrate with a space therebetween; and
a contact projecting from said beam and extending in the direction away from said probe substrate, wherein
at least one of either probe substrate or beam includes a projection in, an area opposite to the other one of said probe substrate or beam and said projection projecting toward the other one of said probe substrate or said beam.

2. The probe according to claim 1, wherein said beam is supported at one end on said probe substrate.

3. The probe according to claim 1, wherein said beam is supported at both ends on said probe substrate.

4. The probe according to claim 1, wherein said projection includes an angled end face with one side being higher than the other to make surface contact with the opposing member which is to be abutted due to deformation of said beam.

5. The probe according to claim 1, wherein at least two projections are provided.

6. The probe according to claim 5, wherein at least one projection of the two projections is arranged on said probe substrate in opposition to said beam, and at least one projection is arrange on said beam in opposition to said probe substrate.

7. The probe according to claim 6, wherein said at least one projection on said probe substrate and said at least one projection on said beam are arranged to be laterally spaced from each other.

8. The probe according to claim 5, wherein said at least one projection on said probe substrate and said at least one projection on said beam are arranged to face each other.

9. The probe according to claim 5, wherein said at least two projections are provided on one side and the other side with a predetermined space therebetween on either said probe substrate or beam.

10. The probe according to claim 1, wherein said projection is made of a shock-absorbing material.

11. A probe comprising:
a probe substrate;
a beam supported on said probe substrate and serpentined toward the direction away from said probe substrate;
a contact projecting from said beam and extending in the direction away from said probe substrate, wherein
said beam includes a projection in an area thereof which faces the other area of the beam formed by curving the beam, the projection projecting toward the opposite area of the beam.
